(19) United States
(12) Patent Application Publication
(10) Pub. No.: US 2010/0315131 A1
(43) Pub. Date: Dec. 16, 2010

(54) Programmable Frequency Divider with Full Dividing Range

(75) Inventors: Chi Sheng Lin, Taipei (TW); Ting-Hsu Chien, Taipei (TW); Chin-Long Wey, Taipei (TW); Chun-Ming Huang, Taipei (TW); Ying-Zong Juang, Taipei (TW)

Correspondence Address: Juan Carlos A. Marquez;c/o Stites & Harbison PLLC, 1199 North Fairfax Street, Suite 900, Alexandria, VA, 22314-1437, US

(73) Assignee: National Chip Implementaion Center National Applied Research Laboratories, Hsinchu City (TW)

(21) Appl. No.: 12/495,107

(22) Filed: Jun. 30, 2009

(30) Foreign Application Priority Data
Jun. 10, 2009 (TW) 098119306

(51) Int. Cl. H03B 19/00

(52) U.S. Cl. 327/117

(57) ABSTRACT

A programmable frequency divider with a full dividing range includes a plurality of cascaded 2/1 frequency dividers. Each of the 2/1 frequency dividers has a first input node, a first output node, a second input node, a second output node and a third input node. The first input node receives a first clock signal divided by the 2/1 frequency divider and outputted as a second clock signal through the first output node. A second logical signal is generated according to the second clock signal, the first clock signal and a first logical signal received from the second input node. The 2/1 frequency divider selectively switches to perform a divide-by-two or divide-by-one operation according to the second logical signal and a first divisor signal received from the third input nodes. The programmable frequency divider provides the full dividing range as the result of utilizing various divisor of the 2/1 frequency divider.

### BACKGROUND OF THE INVENTION

1. Technical Field

The present invention relates to frequency dividers, and more particularly, to a programmable frequency divider having a full dividing range and applicable to a phase-locked loop.

2. Description of Related Art

The basic operational principle of a phase-locked loop is that an oscillator source that presents extremely low frequency variation is implemented to provide a reference frequency and a closed-loop control system controls a frequency variable element so that the frequency variable element has its output frequency which is processed by a frequency divider promptly and stably aligned with the reference frequency in both phase and frequency. For instance, in radio telecommunication application, where frequency drift of signals happens during transmission, a device at the receiving end may implement a phase-locked loop to align the frequency of the receiving device with the drifting frequency to make them have the same phase and the same frequency, thereby achieving phase lock.

FIG. 1 provides a circuit diagram of a conventional phase-locked loop 100. As shown in FIG. 1, the conventional phase-locked loop 100 includes a phase frequency detector 11, a charge pump 12, a loop filter 13, a voltage control oscillator 14, and a frequency divider 15. Therein, the input frequency of the frequency divider 15 is the output frequency Fvco of the voltage control oscillator 14 and thus is the highest frequency through the entire phase-locked loop 100. Consequently, power consumed by the frequency divider 15 takes up to a half of the overall power consumption of the phase-locked loop 100. On the other hand, the divisor N of the frequency divider 15 is for dividing down the output frequency Fvco, to compare with the stable reference frequency in phase and frequency. Therefore, the output frequency Fvco of the phase-locked loop has its frequency range and output frequency resolution subject to the range of the divisor N of the frequency divider 15.

However, the existing 2/3 frequency dividers are limited in their dividing ranges. For example, the minimum divisor provided by a 2/3 frequency divider is 2ⁿ, while the maximum divisor is 2ⁿ⁺¹−1, wherein n is the number of the cascaded dividers. Thus, where three 2/3 frequency dividers are cascaded, the dividing range of the resultant frequency divider is between 8 and 15. In other words, the resultant frequency divider fails to provide any divisor smaller than 8 or greater than 15.

Because of the limited dividing range of the existing 2/3 frequency dividers, the output frequency of a phase-locked loop needs to be divided through a complicated process and compared with the reference frequency in phase and in frequency, so as to achieve phase lock of the output frequency in a wider range. Consequently, not only is the phase-lock effect of the phase-locked loop reduced, but also the power consumption of the phase-locked loop increases, thus leading to lowered output frequency resolution and output frequency range of the phase-locked loop.

### SUMMARY OF THE INVENTION

In view of the shortcomings of the known technology, one objective of the present invention is to provide a programmable frequency divider with a full dividing range, wherein the frequency divider includes a plurality of cascaded 2/1 frequency dividers and each of the frequency dividers performs a divide-by-two or divide-by-one operation, so that by changing the number of the cascaded 2/1 frequency dividers, the programmable frequency divider is enabled to provide all possible divisors.

Another objective of the present invention is to provide a programmable frequency divider with a full dividing range, wherein the number of the cascaded 2/1 frequency dividers is changeable to meet demands, so that the programmable frequency divider can be highly modular.

Another objective of the present invention is to provide a programmable frequency divider with a full dividing range, wherein frequency divider includes a plurality of cascaded 1/2/3 frequency dividers, and each of the frequency dividers performs a divide-by-one, divide-by-two or divide-by-three operation, so that by changing the number of the cascaded 1/2/3 frequency dividers, the programmable frequency divider has the full dividing range. With the same number of the cascaded frequency dividers, 1/2/3 frequency dividers provide the programmable frequency divider with the dividing range that is double the dividing range provided by 2/1 frequency dividers.

Another objective of the present invention is to provide a programmable frequency divider with a full dividing range, wherein since the programmable frequency divider provides the full dividing range, the programmable frequency divider effectively reduces complexity of the dividing operation in a phase-locked loop, thereby improving the phase-lock performance of the phase-locked loop.

To achieve these and other objectives, the present invention provides a programmable frequency divider with a full dividing range. The programmable frequency divider includes a plurality of cascaded 2/1 frequency dividers. Each of the 2/1 frequency dividers has: a first input node for receiving a first clock signal that has a first frequency; a first output node for outputting a second clock signal that is the divided-down first clock signal and has a second frequency; a second input node for receiving a first logical signal; a second output node for outputting a second logical signal according to the first clock signal, the second clock signal and the first logical signal; and a third input node for receiving a first divisor signal and determining to perform a divide-by-two or divide-by-one operation upon the first clock signal according to the first divisor signal and the second logical signal.

To achieve these and other objectives, the present invention further discloses a 2/1 frequency divider. The 2/1 frequency divider includes: a first input node for receiving a first clock signal that has a first frequency; a first output node for outputting a second clock signal that is the divided-down first clock signal and has a second frequency; a second input node for receiving a first logical signal; a second output node for outputting a second logical signal according to the first clock signal, the second clock signal and the first logical signal; and a third input node for receiving a first divisor signal and determining to perform a divide-by-two or divide-by-one operation upon the first clock signal according to the first divisor signal and the second logical signal.

To achieve these and other objectives, the present invention further discloses a programmable frequency divider with a full dividing range. The programmable frequency divider includes a plurality of cascaded 1/2/3 frequency dividers. Each of the 1/2/3 frequency dividers has: a fourth input node for receiving a third clock signal that has a third frequency; a third output node for outputting a fourth clock signal that is the divided-down third clock signal and has a fourth frequency; a fifth input node for receiving a third logical signal; a fourth output node for outputting a fourth logical signal according to the third clock signal, the fourth clock signal and the third logical signal; a sixth input node for receiving a second divisor signal; and a seventh input node for receiving a third divisor signal and determining to divide the third clock signal by one, by two, or by three according to the third divisor signal, the fourth logical signal and the second divisor signal.

To achieve these and other objectives, the present invention further discloses a 1/2/3 frequency divider. The 1/2/3 frequency dividers has: a fourth input node for receiving a third clock signal that has a third frequency; a third output node for outputting a fourth clock signal that is the divided-down third clock signal and has a fourth frequency; a fifth input node for receiving a third logical signal; a fourth output node for outputting a fourth logical signal according to the third clock signal, the fourth clock signal and the third logical signal; a sixth input node for receiving a second divisor signal; and a seventh input node for receiving a third divisor signal and determining to divide the third clock signal by one, by two, or by three according to the third divisor signal, the fourth logical signal and the second divisor signal.

By implementing the present invention, at least the following progressive effects can be obtained:

1. By implementing various numbers of cascaded 2/1 frequency dividers or cascaded 1/2/3 frequency dividers, the programmable frequency divider provides the full dividing range and has the advantage of being modular.

2. The programmable frequency divider with the full dividing range allows improved flexibility in divisor programming, thereby reducing the complexity of frequency division in applied systems.

3. The programmable frequency divider of the asynchronous structure achieves high-speed operation feature.

### BRIEF DESCRIPTION OF THE DRAWINGS

The invention as well as a preferred mode of use, further objectives and advantages thereof will be best understood by reference to the following detailed description of illustrative embodiments when acquire in conjunction with the accompanying drawings, wherein:

FIG. 1 is a circuit diagram of a conventional phase-locked loop;

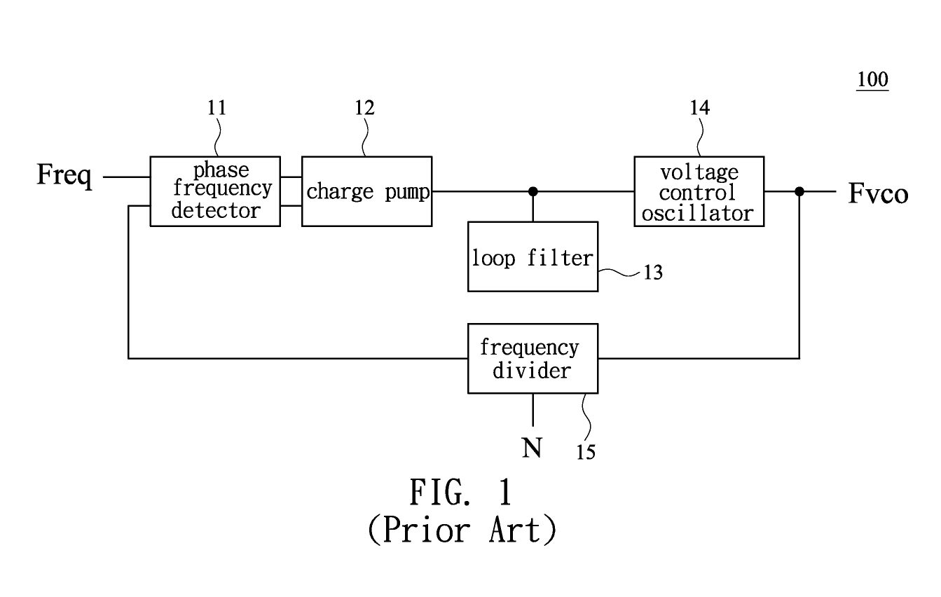

FIG. 2 shows the structure of a programmable frequency divider with a full dividing range according to a first embodiment of the present invention;

FIG. 3 is the structure of a 2/1 frequency divider according to the first embodiment of the present invention;

FIG. 4 is a circuit diagram of the 2/1 frequency divider of FIG. 3;

FIG. 5 is a finite-state machine for the divisor mode of the 2/1 frequency divider of FIG. 3;

FIG. 6 describes a timing diagram of the 2/1 frequency divider of FIG. 3;

FIG. 7 describes a timing diagram of the programmable frequency divider with the full dividing range of the first embodiment;

FIG. 8 shows the structure of a programmable frequency divider with a full dividing range according to a second embodiment of the present invention;

FIG. 9 is the structure of a 1/2/3 frequency divider according to the second embodiment of the present invention;

FIG. 10 is a circuit diagram of the 1/2/3 frequency divider of FIG. 9;

FIG. 11 is a finite-state machine for the divisor mode of the 1/2/3 frequency divider of FIG. 9;

FIG. 12 describes a timing diagram of the 1/2/3 frequency divider of FIG. 12; and

FIG. 13 shows the structure of a programmable frequency divider with a full dividing range according to the first and second embodiment of the present invention.

### DETAILED DESCRIPTION OF THE PREFERRED EMBODIMENT

### First Embodiment

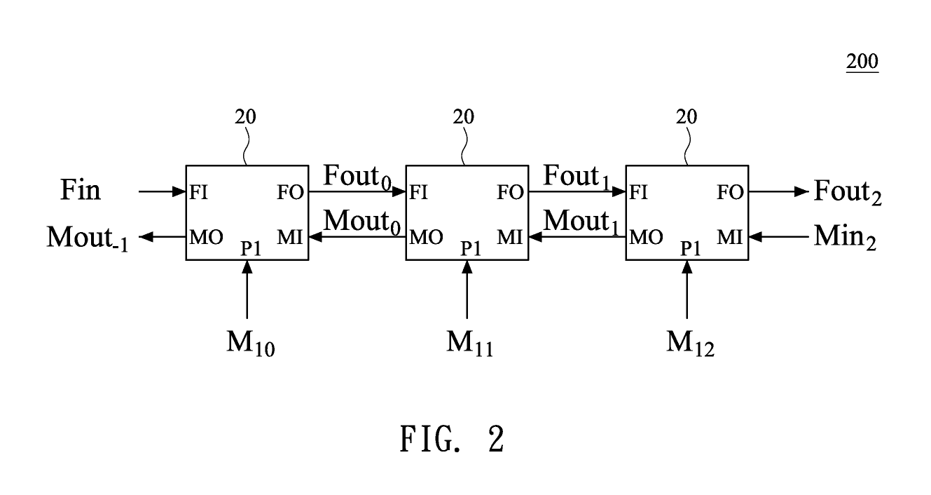

FIG. 2 provides a programmable frequency divider 200 with a full dividing range according to a first embodiment of the present invention. The frequency divider 200 includes a plurality of cascaded 2/1 frequency dividers 20. For example, the frequency divider 200 may be formed by three cascaded 2/1 frequency dividers 20. Each of the 2/1 frequency dividers 20 has a first input node FI, a first output node FO, a second input node MI, a second output node MO and a third input node P1.

Referring to FIG. 2, the programmable frequency divider 200 has the three 2/1 frequency dividers 20 arranged in three stages, namely a first stage, a second stage, and a third stage, from the left to the right. Therein, the first output node FO of the 2/1 frequency divider 20 in each said stage is coupled to the first input node FI of the frequency divider 20 in its succeeding stage while the second output node MO of each said 2/1 frequency divider 20 is coupled to the second input node MI at the previous stage.

The programmable frequency divider 200 has the first input node FI of the 2/1 frequency divider 20 at the first stage receiving a first clock signal Fin. After the frequency dividing operation of all the 2/1 frequency dividers 20, a second clock signal Fout₂ is output by the first output node FO of the 2/1 frequency divider 20 at the last stage. Therein, a frequency ratio between the first clock signal Fin and the second clock signal Fout₂ is just the divisor N programmed in the programmable frequency divider 200.

Each of the 2/1 frequency dividers 20 selectively switches to perform a divide-by-two or divide-by-one operation according to a second logical signal Mout₋₁, Mout₀, or Mout₁ and a first divisor signal M₁₀, M₁₁, or M₁₂ received by the third input nodes P1. The switching process will be described in detail below.

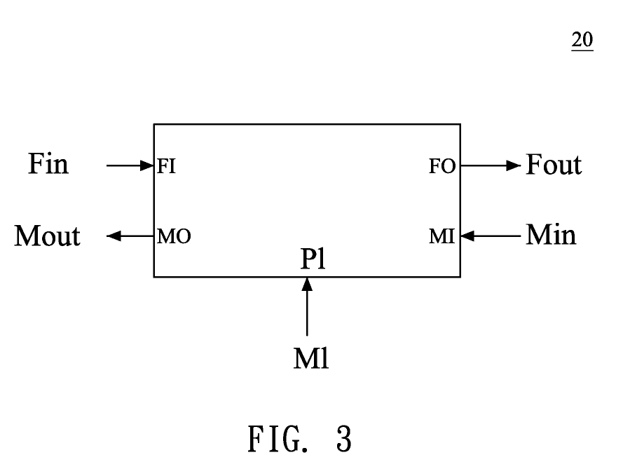

As can be seen in FIG. 3, the first input node FI receives a first clock signal Fin that has a first frequency. Since the programmable frequency divider 200 is based on an asynchronous design, it possesses high processing efficiency and thus allows the input first clock signal to be of a high frequency, such as a frequency of GHz level.

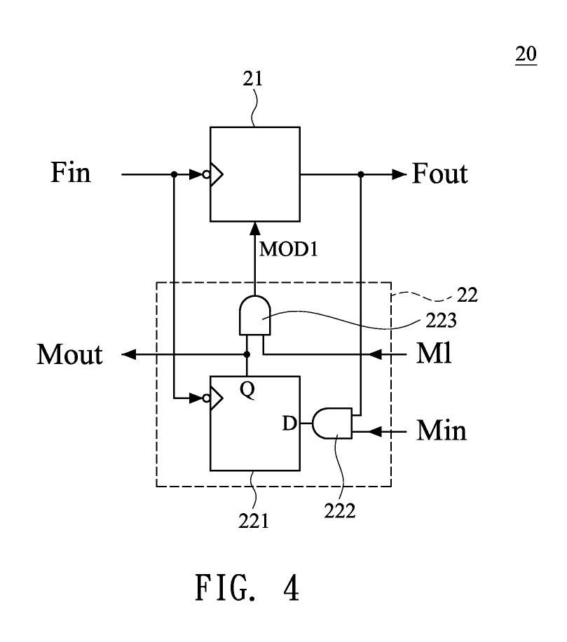

Referring to FIG. 4, the 2/1 frequency divider 20 includes a first operation mode determining circuit 22 and a 2/1 frequency dividing mode circuit 21. The first operation mode determining circuit 22 has a first flip-flop 221, a first AND gate 222, and a second AND gate 223. Therein, the first AND gate 222 and the second AND gate 223 are coupled to a signal input node D and a signal output node Q of the first flip-flop 221, respectively. Moreover, the first clock signal Fin is received by clock signal input nodes of the first operation mode determining circuit 22 and the 2/1 frequency dividing mode circuit 21 simultaneously for acting as a clock signal. The first clock signal Fin may also act as a clock signal for the first flip-flop 221 in the first operation mode determining circuit 22 so as to trigger the first flip-flop 221 by the positive edge or the negative edge, thereby actuating the first operation mode determining circuit 22.

Referring to FIGS. 3 and 4, the first output node FO outputs a second clock signal Fout. The second clock signal Fout is a resultant signal obtained by dividing down the first clock signal Fin and has a second frequency. Therein, a frequency ratio between the first frequency of the first clock signal Fin and the second frequency of the second clock signal Fout is determined by the second logical signal Mout and the first divisor signal M1 of the 2/1 frequency dividers 20.

As can be seen in FIGS. 3 and 4, the second input node MI receives a first logical signal Min, and the first logical signal Min is input to the first AND gate 222 of the first operation mode determining circuit 22. Furthermore, the first logical signal Min may be a fixed logical signal generated by a signal generator. For example, the first logical signal Min may be fixed as logical 0 or logical 1.

Referring to FIG. 4 again, the second clock signal Fout is input to the first AND gate 222 in the form of a logical signal. In other words, the first AND gate 222 receives the first logical signal Min and the second clock signal Fout simultaneously. Thus, when the second clock signal Fout output by the 2/1 frequency divider 20 is an enable logic, the enable logic is output to the first AND gate 222. On the contrary, when the second clock signal Fout output by the 2/1 frequency dividers 20 is a disable logic, the first AND gate 222 receives the disable logic. Thereby, the first AND gate 222 calculates according to the first logical signal Min and the second clock signal Fout, and outputs the calculative result to the signal input node D of the first flip-flop 221. It is to be noted that in defining the enable logic and the disable logic, it is not necessary that logical 0 represents an enable logic and logical 1 represents a disable logic. The definition may vary according to practical circuit designs.

Referring to FIGS. 3 and 4, the second output node MO outputs a second logical signal Mout. The second logical signal Mout is output by the signal output node Q of the first flip-flop 221. Therefore, the second logical signal Mout is generated by the first flip-flop 221 according to the signal received by the signal input node D. In other words, the second clock signal Fout and the first logical signal Min are products of the calculation conducted by the first AND gate 222 and the first flip-flop 221.

Still referring to FIGS. 3 and 4, the third input node PI receives a first divisor signal M1, and the first divisor signal M1 is input to the second AND gate 223 of the first operation mode determining circuit 22. In addition, the first divisor signal M1 is also in the form of a logical signal.

As shown in FIG. 4, the second logical signal Mout is also input to the second AND gate 223, so as to allow the second AND gate 223 to output a first mode control signal MOD1 according to the second logical signal Mout and the first divisor signal M1 to the 2/1 frequency dividing mode circuit 21, thereby controlling the 2/1 frequency dividing mode circuit 21 to switch the 2/1 frequency divider 20 to perform a divide-by-two or divide-by-one operation upon the first clock signal Fin received by the first input node FI.

For instance, when the first logical signal Min and the second clock signal Fout are input to the first AND gate 222 at the same time, and the both are enable logics, the first AND gate 222 outputs the enable logic to the signal input node D of the first flip-flop 221. Then the first flip-flop 221, upon receiving the enable logic, has the signal output node Q thereof outputting the second logical signal Mout that is also an enable logic. Therefore, only when the first logical signal Min and the second clock signal Fout are enable logics simultaneously, it is possible that the second logical signal Mout is an enable logic. Otherwise, the second logical signal Mout shall be a disable logic.

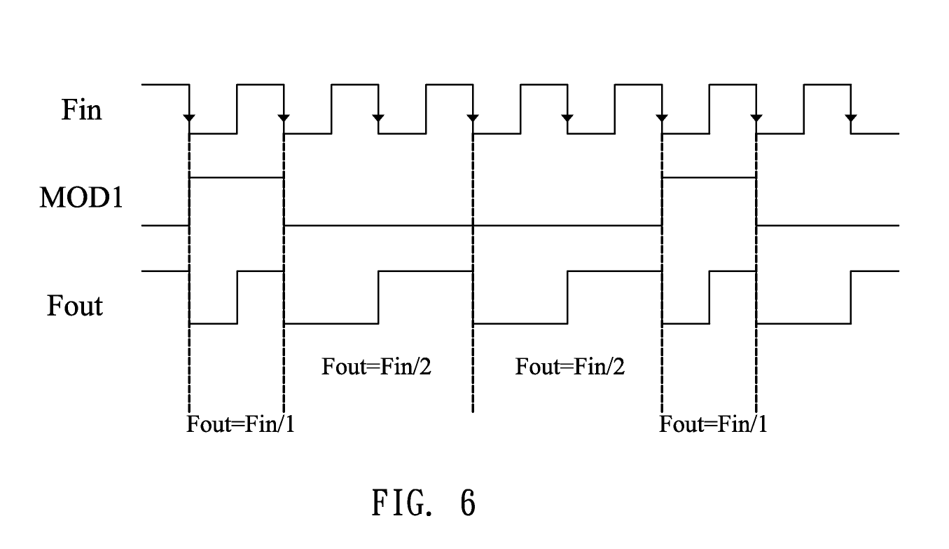

When the first divisor signal M1 is an enable logic and the second logical signal Mout is also an enable logic, the first mode control signal MOD1 as a product of the calculation of the second AND gate 223 is of the divide-by-one mode so that the 2/1 frequency divider 20 is allowed to perform the divide-by-one operation according to the first mode control signal MOD1. At last, the second clock signal Fout output by the first output node FO has the second frequency being the frequency obtained by dividing down the first clock signal Fin by 1 (as shown in FIG. 6, Fout=Fin/1).

On the contrary, when either the first divisor signal M1 or the second logical signal Mout is a disable logic, the first mode control signal MOD1 generated by the second AND gate 223 is of the divide-by-two mode so that the 2/1 frequency divider 20 is allowed to perform the divide-by-two operation. Similarly, the second clock signal Fout output by the first output node MO has the frequency being the frequency obtained by dividing down the first clock signal Fin by 2 (as shown in FIG. 6, Fout=Fin/2).

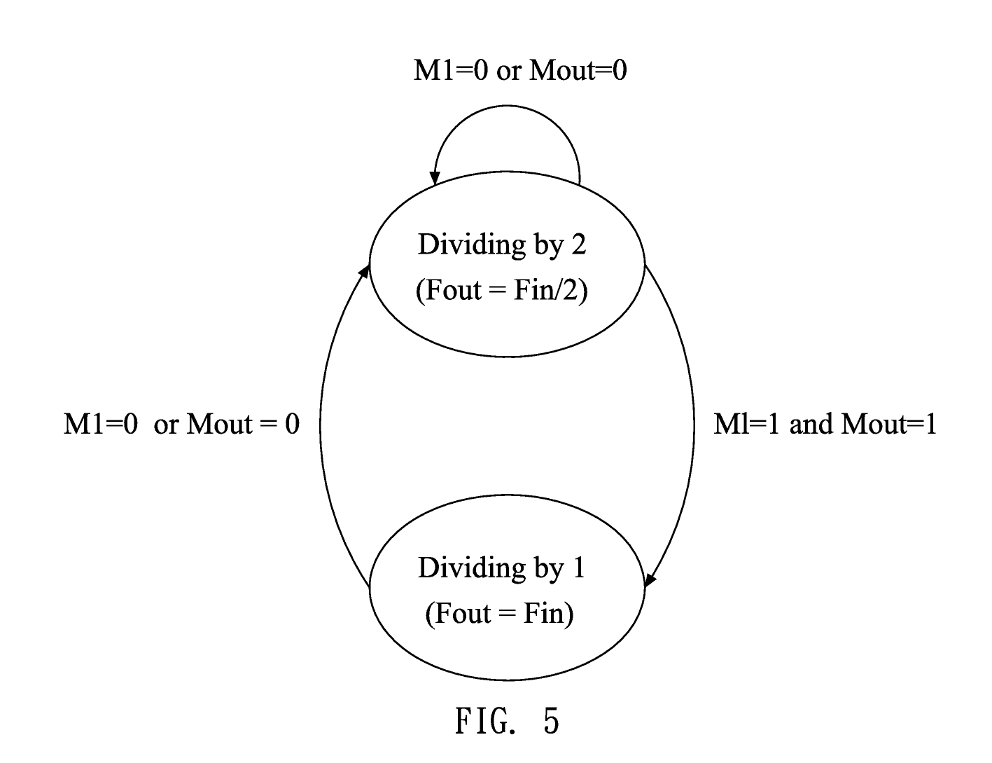

The logical relation between the aforementioned first clock signal Fin, the first divisor signal M1, the second clock signal Fout as well as the second logical signal Mout and the switching operation of the 2/1 frequency dividers 20 between the divide-by-one mode and the divide-by-two mode is as shown in FIG. 5.

Since the programmable frequency divider 200 includes plural cascaded 2/1 frequency dividers 20, when the first logical signal Min₂ is fixed as an enable logic and the first divisor signals M₁₀, M₁₁, M₁₂ of the 2/1 frequency dividers 20 are disable logics, all the 2/1 frequency dividers 20 are in the divide-by-two mode, so the maximum divisor N of the programmable frequency divider 200 is 2ⁿ, wherein n is equal to the number of the cascaded 2/1 frequency dividers 20.

When the first logical signal Min₂, the second logical signals Mout₋₁, Mout₀, Mout₁ and the first divisor signals M₁₀, M₁₁, M₁₂ of the 2/1 frequency dividers 20 at all the stages are all enable logics, all the 2/1 frequency dividers 20 are in the divide-by-one mode. Consequently, the minimum divisor N of the programmable frequency divider 200 is 1. Thereby, the programmable frequency divider 200 is capable of providing the divisor N in the full dividing range, namely from 1 to 2ⁿ, and the divisor N may be described by the equation below:

N=2ⁿ−M₀2⁰−M₁2¹−M₂2²− . . . −Mₙ₋₁2ⁿ⁻¹

Therein, M₀, M₁, M₂ . . . Mₙ₋₁ each represents the first divisor signal M1 of the 2/1 frequency divider 20 at a respective said stage, while n is the number of the 2/1 frequency dividers 20 cascaded. The divisor N may be provided by the programmable frequency divider 200 may be described by the equation below:

N=2²−M₁₀2⁰−M₁₁2¹−M₁₂2²

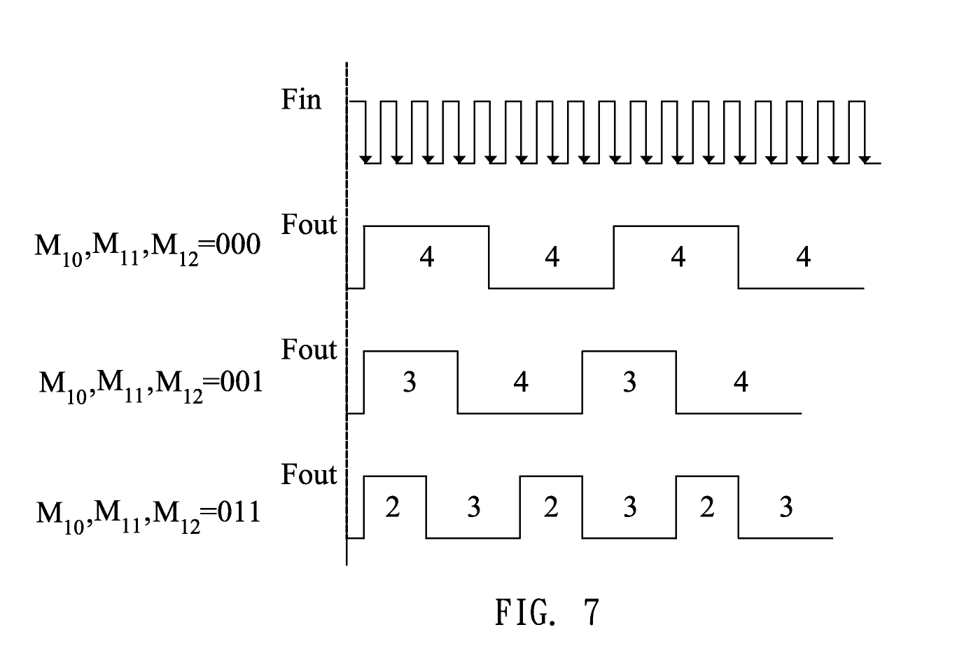

For example, assuming herein that logical 1 is an enable logic and logical 0 is a disable logic, referring to FIG. 7, in a programmable frequency divider 200 including three 2/1 frequency dividers 20 cascaded (as shown in FIG. 2), where the first logical signal Min₂ is fixed as logical 1, when the first divisor signals M₁₀, M₁₁, M₁₂ are all input as logical 0 (M₁₀, M₁₁, M₁₂=000), and the divisor N is 8 (N=2³), the second frequency of the second clock signal Fout₂ is a product of dividing the first frequency of the first clock signal Fin by 8. On the other hand, when the first divisor signals M₁₀, M₁₁, M₁₂ are input as 001 or 011, respectively (M₁₀, M₁₁, M₁₂=001 or 011), the divisor N of the programmable frequency divider 200 is correspondingly 7(N=2³−2⁰) or 5(N=2³−2⁰−2¹).

As described previously, by changing the first divisor signals M₁₀, M₁₁, M₁₂ input to every said 2/1 frequency divider 20, or by changing the number of the 2/1 frequency dividers 20 cascaded, the programmable frequency divider 200 can be programmed with the divisor N of different values. Consequently, highly modular design of the programmable frequency divider 200 and excellent flexibility of the divisor N can be achieved, thereby reducing the complexity of frequency division in applied systems.

### Second Embodiment

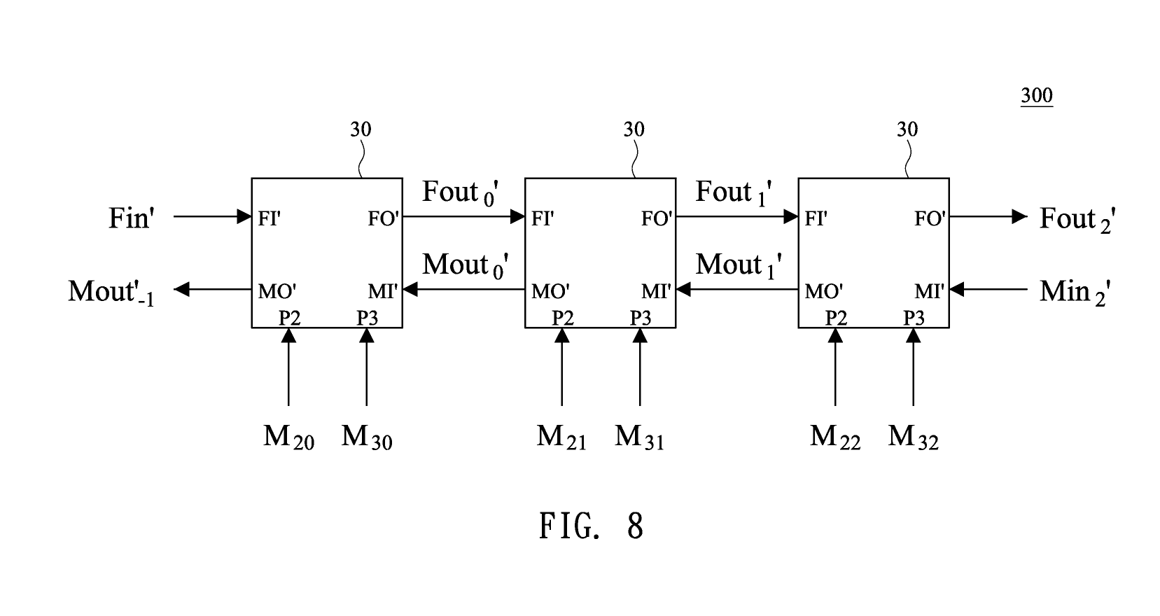

FIG. 8 provides a programmable frequency divider 300 with a full dividing range according to a second embodiment of the present invention. The frequency divider 300 includes a plurality of cascaded 1/2/3 frequency dividers 30. For example, the programmable frequency divider 300 may have three 1/2/3 frequency dividers 30. Each of the 1/2/3 frequency dividers 30 has a fourth input node FI′, a third output node FO′, a fifth input node MI′, a fourth output node MO′, a sixth input node P2, and a seventh input node P3.

Referring to FIG. 8, the programmable frequency divider 300 has the three 1/2/3 frequency dividers 30 arranged in three stages, namely a first stage, a second stage, and a third stage, from the left to the right. Therein, the third output node FO′ of the 1/2/3 frequency divider 30 in a respective said stage is coupled to the fourth input node FI′ of the 1/2/3 frequency divider 30 in the succeeding stage while the fourth output node MO′ of each said 1/2/3 frequency divider 30 is coupled to the fifth input node MI′ at the previous stage.

The programmable frequency divider 300 has the fourth input node FI′ of the 1/2/3 frequency divider 30 at the first stage receiving a third clock signal Fin′. After the dividing operation of all the 1/2/3 frequency dividers 30, a fourth clock signal Fout′₂ is output by the third output node FO′ of the 1/2/3 frequency divider 30 at the last stage. Therein, a frequency ratio between the third clock signal Fin′ and the fourth clock signal Fout′₂ is determined by a fourth logical signal Mout′, a second divisor signal M2 and a third divisor signal M3 of the 1/2/3 frequency divider 30.

Each of the 1/2/3 frequency dividers 30 selectively switches to perform a divide-by-one, divide-by-two, or divide-by-three operation according to the fourth logical signal Mout′₋₁, Mout′₀, or Mout′₁ of the fourth output node, the second divisor signals M₂₀, M₂₁, or M₂₂ received by the sixth input node P2, and the third divisor signal M₃₀, M-₃₁, or M₃₂ received at the seventh input node P3. The switching process will be described in detail below.

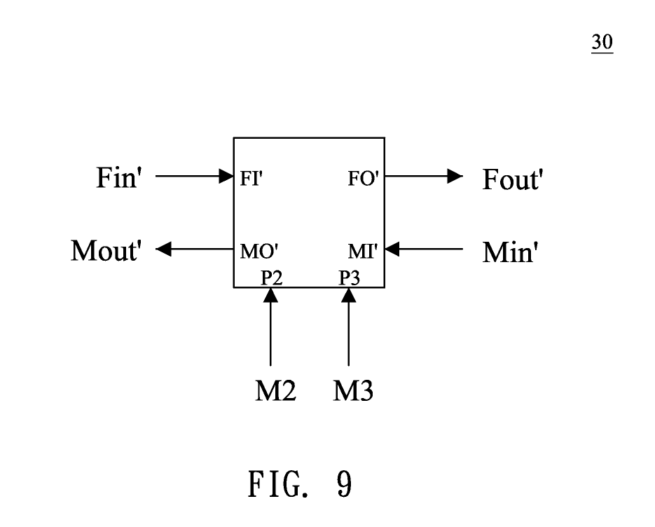

As can be seen in FIG. 9, the fourth input node FI′ receives the third clock signal Fin′ that has a third frequency. Since the programmable frequency divider 300 is based on an asynchronous design, it possesses high processing efficiency and thus allows the input third clock signal to be of a high frequency, such as a frequency of GHz level.

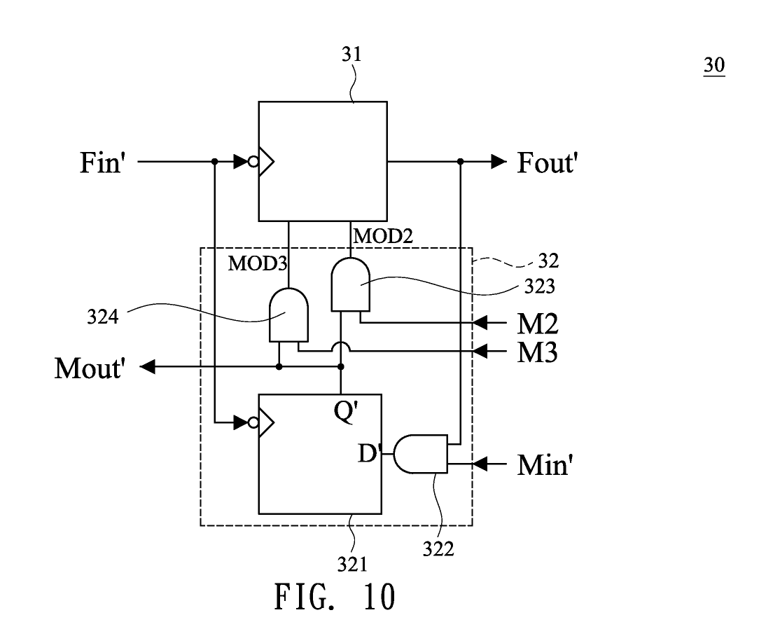

Referring to FIG. 10, the 1/2/3 frequency divider 30 includes a second operation mode determining circuit 32 and a 1/2/3 frequency dividing mode circuit 31. The second operation mode determining circuit 32 has a second flip-flop 321, a third AND gate 322, a fourth AND gate 323, and a fifth AND gate 324. Therein, the third AND gate 322 is coupled to a signal input node D′ of the second flip-flop 321 while the fourth AND gate 323 and the fifth AND gate 324 are coupled to a signal output node Q′ of the second flip-flop 321.

Moreover, the third clock signal Fin′ is received by clock signal input nodes of the second operation mode determining circuit 32 and the 1/2/3 frequency dividing mode circuit 31 simultaneously for acting as a clock signal of the 1/2/3 frequency dividing mode circuit 31. The third clock signal Fin′ may also act as a clock signal for the second flip-flop 321 in the second operation mode determining circuit 32 so as to trigger the second flip-flop 321 by the positive edge or the negative edge, thereby actuating the second operation mode determining circuit 32.

Referring to FIGS. 9 and 10, the third output node FO′ outputs a fourth clock signal Fout′. The fourth clock signal Fout′ is a resultant signal obtained by dividing down the third clock signal Fin′ and has a fourth frequency. Therein, a frequency ratio between the third frequency of the third clock signal Fin′ and the fourth frequency of the fourth clock signal Fout′ is just the divisor N programmed in the 1/2/3 frequency dividers 30.

As can be seen in FIGS. 9 and 10, the fifth input node MI′ receives a third logical signal Min′, and the third logical signal Min is input to the third AND gate 322 of the second operation mode determining circuit 32. Furthermore, the third logical signal Min′ may be a fixed logical signal generated by a signal generator. For example, the third logical signal Min′ may be fixed as logical 0 or logical 1.

Referring to FIG. 10, the fourth clock signal Fout′ is input to the third AND gate 322 in the form of a logical signal also. In other words, the third AND gate 322 may receive the third logical signal Min′ and the fourth clock signal Fout′ simultaneously. Thus, when the fourth clock signal Fout′ output by the 1/2/3 frequency divider 30 is an enable logic, the enable logic is output to the third AND gate 322. On the contrary, when the fourth clock signal Fout′ output by the 1/2/3 frequency dividers 30 is a disable logic, the third AND gate 322 receives the disable logic. Thereby, the third AND gate 322 calculates according to the third logical signal Min′ and the fourth clock signal Fout′, and outputs the calculative result to the signal input node D′ of the second flip-flop 321. It is to be noted that in defining the enable logic and the disable logic, it is not necessary that logical 0 represents an enable logic and logical 1 represents a disable logic. The definition may vary according to practical circuit designs.

For instance, when the third logical signal Min′ and the fourth clock signal Fout′ are input to the third AND gate 322 at the same time, and the both are enable logics, the third AND gate 322 outputs the enable logic to the signal input node D′ of the second flip-flop 321. Then the second flip-flop 321, upon receiving the enable logic, has the signal output node Q′ thereof outputting the fourth logical signal Mout′ that is also an enable logic. In virtue of the presence of the third AND gate 322, only when the third logical signal Min′ and the fourth clock signal Fout′ are both enable logics, it is possible that the fourth logical signal Mout′ is an enable logic. Otherwise, the fourth logical signal Mout′ shall be a disable logic.

Referring to FIGS. 9 and 10, the fourth output node MO′ outputs a fourth logical signal Mout′. The fourth logical signal Mout′ is output by the signal output node Q′ of the second flip-flop 321. Therefore, the fourth logical signal Mout′ is generated by the second flip-flop 321 that calculates the signal received at the signal input node D′. In other words, the third logical signal Min′ and the fourth clock signal Fout′ are products of the calculation conducted by the third AND gate 322 and the second flip-flop 321.

Referring to FIGS. 9 and 10, the sixth input node P2 receives a second divisor signal M2, and the second divisor signal M2 is input to the fourth AND gate 323 of the second operation mode determining circuit 32. In addition, the second divisor signal M2 is also in the form of a logical signal.

Referring to FIGS. 9 and 10, the seventh input node P3 receives a third divisor signal M3, and the third divisor signal M3 is input to the fifth AND gate 324 of the second operation mode determining circuit 32. In addition, the third divisor signal M3 is also in the form of a logical signal.

As shown in FIG. 10, the fourth logical signal Mout′ is also input to the fourth AND gate 323 and the fifth AND gate 324, so as to allow the fourth AND gate 323 to output a second mode control signal MOD2 according to the fourth logical signal Mout′ and the second divisor signal M2 and so as to allow the fifth AND gate 324 to output a third mode control signal MOD3 according to the fourth logical signal Mout′ and the third divisor signal M3. The second mode control signal MOD2 and the third mode control signal MOD3 are received by the 1/2/3 frequency dividing mode circuit 31, thereby controlling the 1/2/3 frequency dividing mode circuit 31 to switch the 1/2/3 frequency dividers 30 to perform a divide-by-one, divide-by-two, or divide-by-three operation upon the third clock signal Fin′ received by the fourth input node FI.′

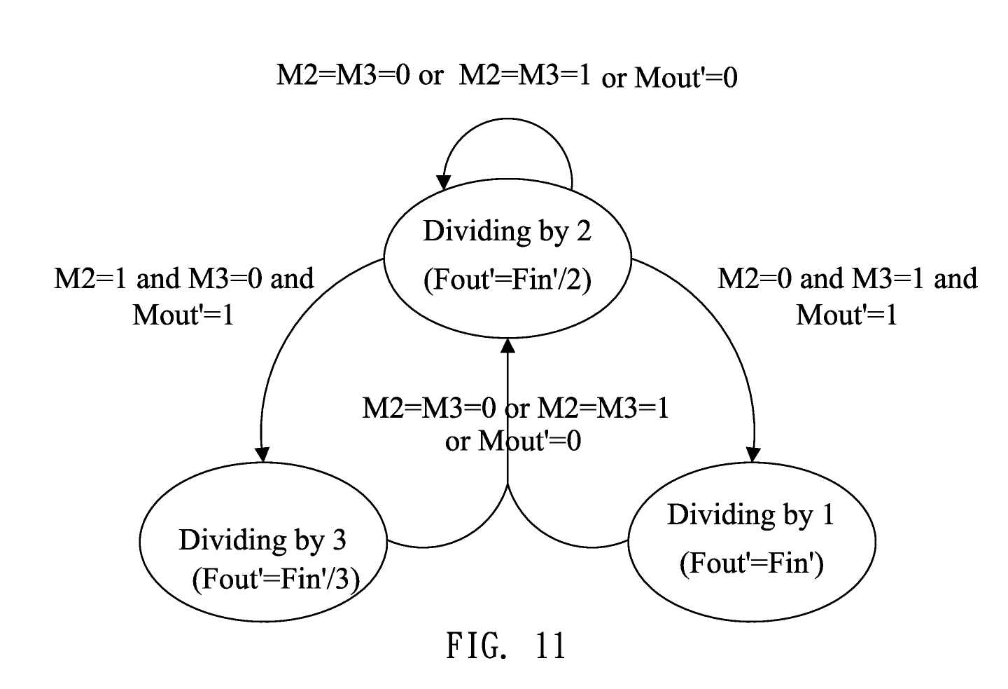

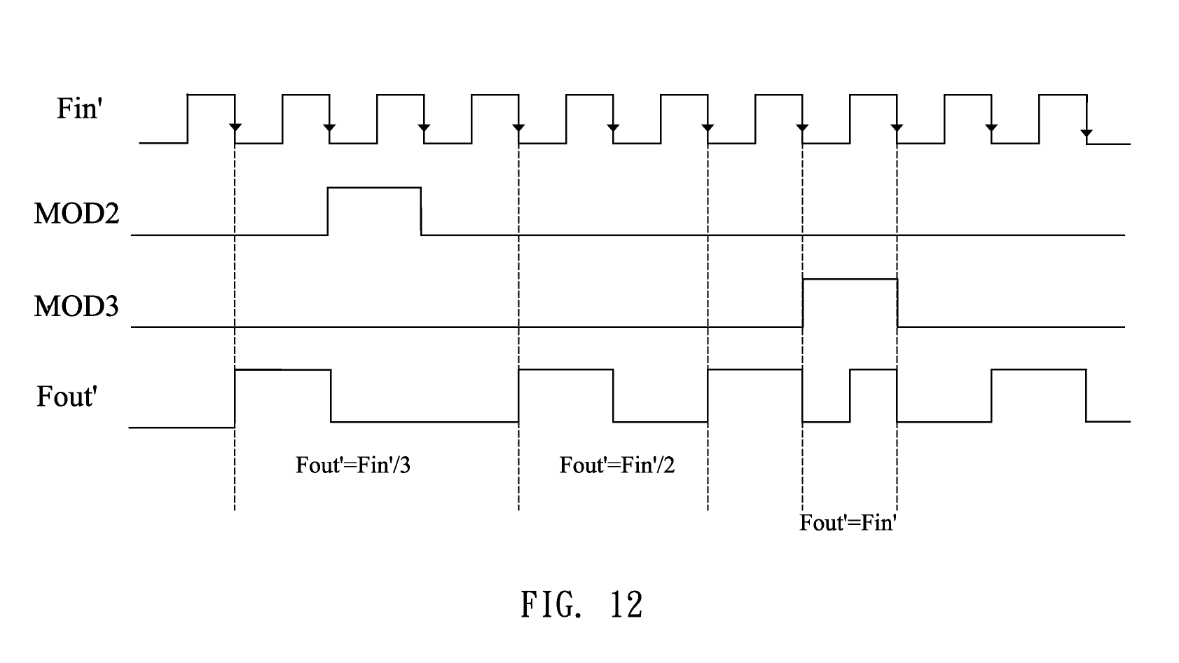

The calculative logic and calculative result of 1/2/3 frequency dividing mode circuit 31 are shown in FIG. 11 and FIG. 12, respectively. It is herein assumed that logical 1 is an enable logic and logical 0 is a disable logic. When the fourth logical signal Mout′ and the third divisor signal M3 are enable logics (Mout′·M3=1), while the second divisor signal M2 is a disable logic (M2=0), the second mode control signal MOD2 and the third mode control signal MOD3 generated at this time switch the 1/2/3 frequency dividers 30 to perform the divide-by-one operation and make the third output node FO′ output the fourth clock signal Fout′. The second frequency of the fourth clock signal Fout′ is a product of dividing the third clock signal Fin′ by 1(Fout′=Fin′).

When the fourth logical signal Mout′ and the second divisor signal M2 are both enable logics (Mout′·M2=1), while the third divisor signal M3 is a disable logic (M3=0), the 1/2/3 frequency dividers 30 are switched to perform the divide-by-three operation and the fourth clock signal Fout′ is output by the third output node FO′. The fourth frequency of the fourth clock signal Fout′ is a product of dividing the third clock signal Fin′ by 3 (Fout′=Fin′/3).

Furthermore, when the fourth logical signal Mout′ is a disable logic or the second divisor signal M2 as well as the third divisor signal M3 are both disable logics, or the second divisor signal M2 as well as the third divisor signal M3 are both enable logics (Mout′=0 or M2·M3=0 or M2·M3=1), the 1/2/3 frequency divider 30 is switched by the 1/2/3 frequency dividing mode circuit 31 to perform the divide-by-two operation and the fourth clock signal Fout′ is output by the third output node FO′. The fourth clock signal Fout′ output by the third output node FO′ is a product of dividing the third clock signal Fin′ by 2 (Fout′=Fin′/2).

Since the programmable frequency divider 300 includes plural said 1/2/3 frequency dividers 30 cascade together, when the second divisor signals M₂₀, M₂₁, M₂₂ of the 1/2/3 frequency dividers 30 at all the stages are fixed as disable logics, it means that each said 1/2/3 frequency divider 30 is only allowed to perform the divide-by-two or divide-by-one operation, i.e. acting as 2/1 frequency dividers 20.

When the third divisor signals M₃₀, M₃₁, M₃₂ of the 1/2/3 frequency dividers 30 at all the stages are fixed as disable logics, it means that each said 1/2/3 frequency divider 30 is only allowed to perform the divide-by-two or divide-by-three operation, i.e. acting as 2/3 frequency dividers.

Therefore, the maximum divisor N of the programmable frequency divider 300 comes to 2ⁿ⁺¹−1 and the minimum divisor N is 1. Thus, the programmable frequency divider 300 provides the full range of the divisor N, namely 1 to 2ⁿ⁺¹−1. wherein n is equal to the number of the cascaded 1/2/3 frequency dividers 30. The divisor N may be described by the equation below:

N=2ⁿ+(M′₀−M″₀)2⁰+(M′₁−M″₁)2¹+(M′₂−M″₂)2²+ . . . +(M′ₙ₋₁−M″ₙ₋₁)2ⁿ⁻¹

Therein, M′₀, M′₁, M′₂ . . . M′ₙ₋₁ each represents the second divisor signal M2 of the 1/2/3 frequency divider 30 at a respective said stage, and M″₀, M″₁, M″₂ . . . M″ₙ₋₁ each represents the third divisor signal M3 of the 1/2/3 frequency divider 30 at a respective said stage, while n is the number of the 1/2/3 frequency dividers 30 cascaded.

The divisor N provided by the programmable frequency divider 300 of FIG. 8 may be described by the equation below:

N=2³+(M₂₀−M₃₀)2⁰+(M₂₁−M₃₁)2¹+(M₂₂−M₃₂)2²

As described previously, by changing the second divisor signals M₂₀, M₂₁, M₂₂ or the third divisor signals M₃₀, M₃₁, M₃₂ input to every said 1/2/3 frequency divider 30, or by changing the number of the 1/2/3 frequency dividers 30 cascaded in the programmable frequency divider 300, the programmable frequency divider 300 is programmable to have different divisors N. Consequently, highly modular design of the programmable frequency divider 300 and excellent flexibility of the divisor N can be achieved, thereby reducing the complexity of frequency division in applied systems.

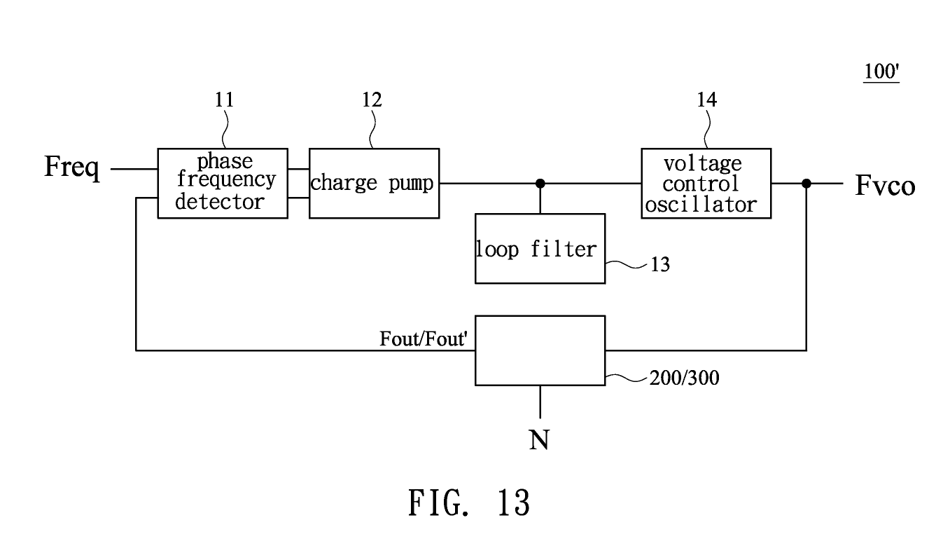

Referring to FIG. 13, when the programmable frequency divider 200/300 is applied to a phase-locked loop 100′, the second clock signal Fout or the fourth clock signal Fout′ is input to the phase frequency detector 11 for being compared with a reference frequency Freq in phase and in frequency. Since the phase-locked loop 100′ features for negative feedback, the final goal of the system is to equalize the reference frequency Freq and the second frequency of the second clock signal Fout or the fourth frequency of the fourth clock signal Fout′. In virtue of the full range of the divisor N provided by the programmable frequency divider 200/300, the frequency divisor can be obtained in a widened range, so as to enable the phase-locked loop to perform multi-band output.

Moreover, the programmable frequency divider 200 may be realized basing on a modulized structure and asynchronous design, the required area for circuits are quite small while the profit of high-speed processing, low costs, and low power consumption can be achieved. Besides, the programmable frequency divider 200 featuring for full swing has an enlarged application scope, including, but not limited to, CPU (central processing unit), DSP (digital signal processor), wireless network, bluetooth, and so on.

The present invention has been described with reference to the preferred embodiments and it is understood that the embodiments are not intended to limit the scope of the present invention. Moreover, as the contents disclosed herein should be readily understood and can be implemented by a person skilled in the art, all equivalent changes or modifications which do not depart from the concept of the present invention should be encompassed by the appended claims.

What is claimed is:

1. A programmable frequency divider with a full dividing range, wherein the programmable frequency divider includes a plurality of cascaded 2/1 frequency dividers and each of the frequency dividers comprises:
a first input node for receiving a first clock signal, wherein the first clock signal has a first frequency;
a first output node for outputting a second clock signal, wherein the second clock signal is the divided-down first clock signal and has a second frequency;
a second input node for receiving a first logical signal;
a second output node for outputting a second logical signal according to the first clock signal, the second clock signal and the first logical signal; and
a third input node for receiving a first divisor signal and determining to divide the first clock signal by two or by one according to the first divisor signal and the second logical signal.

2. The programmable frequency divider of claim 1, for performing following steps:
where the second logical signal and the first divisor signal are both enable logics, the second clock signal output by the first output node being a result of dividing the first clock signal by 1; and
where one of the second logical signal and the first divisor signal is a disable logic, the second clock signal output by the first output node being a result of dividing the first clock signal by 2.

3. A 2/1 frequency divider, comprising:
a first input node for receiving a first clock signal, wherein the first clock signal has a first frequency;
a first output node for outputting a second clock signal, wherein the second clock signal is the divided-down first clock signal and has a second frequency;
a second input node for receiving a first logical signal;
a second output node for outputting a second logical signal according to the first clock signal, the second clock signal and the first logical signal; and
a third input node for receiving a first divisor signal and determining to divide the first clock signal by two or by one according to the first divisor signal and the second logical signal.

4. The 2/1 frequency divider of claim 3, for performing following steps:
where the second logical signal and the first divisor signal are both enable logics, the second clock signal output by the first output node being a result of dividing the first clock signal by 1; and
where one of the second logical signal and the first divisor signal is a disable logic, the second clock signal output by the first output node being a result of dividing the first clock signal by 2.

5. A programmable frequency divider with a full dividing range, wherein the programmable frequency divider includes a plurality of cascaded 1/2/3 frequency dividers and each of the 1/2/3 frequency dividers comprises:
a fourth input node for receiving a third clock signal, wherein the third clock signal has a third frequency;
a third output node for outputting a fourth clock signal, wherein the fourth clock signal is the divided-down third clock signal and has a fourth frequency;
a fifth input node for receiving a third logical signal;
a fourth output node for outputting a fourth logical signal according to the third clock signal, the fourth clock signal and the third logical signal;
a sixth input node for receiving a second divisor signal; and
a seventh input node for receiving a third divisor signal and determining to divide the third clock signal by one, by two, or by three according to the third divisor signal, the fourth logical signal and the second divisor signal.

6. The frequency divider of claim 5, for performing following steps:
where the fourth logical signal and the third divisor signal are both enable logics while the second divisor signal is a disable logic, the fourth clock signal output by the third output node being a result of dividing the third clock signal by 1;
where the fourth logical signal and the second divisor signal are both enable logics while the third divisor signal is a disable logic, the fourth clock signal output by the third output node being a result of dividing the third clock signal by 3; and
where the fourth logical signal is a disable logic while the second divisor signal and the third divisor signal are both disable logics or where the fourth logical signal is a disable logic while the second divisor signal and the third divisor signal are both enable logics, the fourth clock signal output by the third output node being a result of dividing the third clock signal by 2.

7. A 1/2/3 frequency divider, comprising:
a fourth input node for receiving a third clock signal, wherein the third clock signal has a third frequency;
a third output node for outputting a fourth clock signal, wherein the fourth clock signal is the divided-down third clock signal and has a fourth frequency;
a fifth input node for receiving a third logical signal;
a fourth output node for outputting a fourth logical signal according to the third clock signal, the fourth clock signal and the third logical signal;
a sixth input node for receiving a second divisor signal; and
a seventh input node for receiving a third divisor signal and determining to divide the third clock signal by one, by two, or by three according to the third divisor signal, the fourth logical signal and the second divisor signal.

8. The 1/2/3 frequency divider of claim 7, for performing following steps:
where the fourth logical signal and the third divisor signal are both enable logics while the second divisor signal is a disable logic, the fourth clock signal output by the third output node being a result of dividing the third clock signal by 1;
where the fourth logical signal and the second divisor signal are both enable logics while the third divisor signal is a disable logic, the fourth clock signal output by the third output node being a result of dividing the third clock signal by 3; and
where the fourth logical signal is a disable logic while the second divisor signal and the third divisor signal are both disable logics or where the fourth logical signal is a disable logic while the second divisor signal and the third divisor signal are both enable logic, the fourth clock signal output by the third output node being a result of dividing the third clock signal by 2.
